(19) United States
(12) Patent Application Publication
(10) Pub. No.: US 2006/0289800 A1
(43) Pub. Date: Dec. 28, 2006

(54) Implanting a substrate using an ion beam

(76) Inventors: Adrian John Murrell, Horsham (GB); Steven Underwood, Horsham (GB); Majeed Ali Foad, Sunnyvale, CA (US)

Correspondence Address: Robert W. Mulcahy;Applied Materials, Inc., Box 450A, Santa Clara, CA, 95052, US

(21) Appl. No.: 11/386,090

(22) Filed: Mar. 22, 2006

(30) Foreign Application Priority Data
Mar. 22, 2005 (GB) 0505829.2
Sep. 29, 2005 (GB) 0519852.8

(51) Int. Cl. H01J 37/08

(52) U.S. Cl. 250/492.21

(57) ABSTRACT

This invention relates to a method of implanting a substrate comprising scanning an ion beam relative to a substrate along a series of scan lines extending in a first direction, causing relative rotation between the substrate and the ion beam, scanning the ion beam along a second series of scan lines in a different direction. The implant recipe is changed during scanning in each direction such that different regions are produced during each scanning step. The regions so formed during the two scanning steps overlap such that different parts of the substrate receive different doses according to different recipes during the implantation process. The different recipes may result in different dopant concentrations, doping depths or even different dopant species.

### FIELD OF THE INVENTION

This invention relates to a method of implanting a substrate using an ion beam where there is relative motion between the substrate and the ion beam.

### BACKGROUND OF THE INVENTION

Ion implanters are well known and generally conform to a common design as follows. An ion source produces a mixed beam of ions from a precursor gas or the like. Only ions of a particular species are usually required for implantation in a substrate, for example a particular dopant for implantation in a semiconductor wafer. The required ions are selected from the mixed ion beam using a mass-analysing magnet in association with a mass-resolving slit. Hence, an ion beam containing almost exclusively the required ion species emerges from the mass-resolving slit to be transported to a process chamber where the ion beam is incident on a substrate held in place in the ion beam path by a substrate holder.

Often, the cross-sectional profile of the ion beam is smaller than the substrate to be implanted. In order to ensure ion implantation across the whole of the substrate, the ion beam and substrate are moved relative to one another such that the ion beam scans the entire substrate surface. This may be achieved by (a) deflecting the ion beam to scan across the substrate that is held in a fixed position, (b) mechanically moving the substrate whilst keeping the ion beam path fixed or (c) a combination of deflecting the ion beam and moving the substrate. Generally, relative motion is effected such that the ion beam traces a raster pattern on the substrate.

Our co-pending U.S. patent application Ser. No. 10/119290 describes an ion implanter of the general design described above. A single substrate is held in a moveable substrate holder. While some steering of the ion beam is possible, the implanter is operated such that ion beam follows a fixed path during implantation. Instead, the substrate holder is moved along two orthogonal axes to cause the ion beam to scan over the substrate following a raster pattern.

The above design is suitable for serial processing of wafers. Alternatively, wafers may be batch processed and this is most frequently done by placing the wafers on the arms of a spoked wheel that is then rotated. The rotating wafers pass through the ion beam which is scanned in a radial direction to ensure the entire wafer is implanted.

The substrate may be a semiconductor wafer upon which thousands of semiconductor devices are fabricated. Generally, each wafer will be implanted to dope the wafer according to a particular recipe. This ensures that each of the devices on the wafer receives a uniform dosing, such that each device on the wafer will be identical to the others. Experiments may be performed to deduce the optimal parameters that define a particular recipe to achieve the desired doping of devices (or even indirectly, i.e. to determine a particular recipe to achieve desired operational characteristics of a device).

Implanting each wafer to produce identical devices has the disadvantage that many more devices may be produced than may be required, and each semiconductor device may be worth hundreds of dollars As each device is so expensive, such waste is highly undesirable.

To address this problem, it is known to implant different areas of a substrate separately, i.e. to trace a raster pattern over a fraction of the substrate. However, this requires the ion beam to be stopped and turned around on the substrate. This slowed motion results in that part of the substrate receiving an increased dose, contrary to requirements.

An alternative approach is provided by EP-A-1,306,879 that describes a hybrid ion implanter. The ion beam is scanned across the substrate to form a raster pattern where the ion beam is scanned electromagnetically in one direction and the substrate is scanned mechanically in the other direction. The speed of the scan is changed in one of two ways. In a first mode, the first half of the substrate is scanned at a first speed, and the speed of the scan changed during the middle scan line such that the second half of the substrate is scanned at a second speed. In a second mode the speed of the scan is changed across the midpoint of each scan line.

With either mode, a substrate results that has different doping levels in two halves according to the different scan speeds, but is otherwise identical. The wafer may then be rotated and the process repeated. For example, the substrate may be rotated through 90° thereby arriving at a substrate with four quadrants having different doping levels. EP-A-1,306,879 still suffers a disadvantage in that the ion beam is on the substrate as the scan speed is changed. Accordingly, a small portion of the substrate remains that has been exposed to a varying doping level that will not meet that specified for either of the types of device being produced.

### SUMMARY OF THE INVENTION

Against this background, and from a first aspect, the present invention resides in a method of implanting a substrate using an ion beam, comprising: causing relative movement between the substrate and the ion beam such that the ion beam scans across the substrate along a series of scan lines that extend in a first direction relative to the substrate, thereby to implant the substrate in a first pass; causing relative rotation between the substrate and the ion beam; and repeating the step of causing relative movement between the substrate and the ion beam such that the ion beam now follows a series of scan lines that extend in a second, different direction relative to the substrate, thereby to implant the substrate in a second pass.

The method further comprises: performing a first part of the first pass according to a first implant recipe, changing a first property of the ion beam or substrate, and performing a second part of the first pass according to a second implant recipe thereby forming first and second regions of the substrate; and performing a first part of the second pass according to a third implant recipe, changing a second, different property of the ion beam or substrate, and performing a second part of the second pass according to a fourth implant recipe thereby forming third and fourth regions of the substrate. Both the third and fourth regions overlap the first and second regions.

Thus, the above method allows different parts of the substrate to receive different doses according to different recipes during the implantation process. The different recipes may result in different dopant concentrations, doping depths or even different dopant species. Accordingly, if the substrate comprises a plurality of individual devices, not all devices will have the same properties. This allows processing of a single wafer to produce different devices.

Furthermore, the method may be used in experiments to determine the effect on devices of changes in the recipe that follow from the changes in the two or more properties of the ion beam. Such a method is particularly useful where two interdependent properties are changed. Where the rotation is through 90°, the substrate is effectively divided by Cartesian co-ordinates, with variation of each property corresponding to each axis. Thus the substrate effectively becomes a map relating the variation of the two properties.

The properties to be changed may be selected from a variety of experimental parameters. The requirement for the property is that by altering it, the resultant dosing of the substrate is changed. Examples of the property and how it may be changed are as follows. The position of the substrate may be changed, e.g. the substrate may be tilted relative to the ion beam such that the angle of incidence varies between the first and second relative motions. This affects implant depth and also how different features are implanted (i.e. shadowing behind edges on the wafer). How the regions are arranged across the substrate to be implanted may be changed. Overlapping regions ensure different areas of the substrate receive different doses because of the different directions of the scan lines during the first and second relative motions. The ion beam current may be varied to adjust the dosing level, although this may also be effected by changing the scanning speed of the ion beam/substrate holder or the overlap between adjacent scan lines where the ion beam is scanned relative to the substrate in a raster pattern. The ion beam energy may be altered to adjust the depth of implant. Other examples include changing the ion beam species, the ion beam profile or the ion beam divergence. In addition, where a plasma flood system is used in front of the substrate, the operational settings of the plasma flood system may be varied.

There may be some commonality between the first, second, third and fourth recipes. For example, in a contemplated embodiment, the first and third implant recipes are the same. Of course, a pass may comprise forming more than two regions, each region being implanted according to a different recipe or some regions being implanted according to a shared recipe. The regions may be of equal size or may be differently sized. More than two passes may be used to implant the substrate.

According to a second aspect, the present invention resides in a method of implanting a substrate using an ion beam, comprising: causing relative movement between the substrate and the ion beam such that the ion beam scans across the substrate along a series of scan lines that extend in a first direction relative to the substrate, thereby to implant the substrate in a first pass; causing relative rotation between the substrate and the ion beam; and repeating the step of causing relative movement between the substrate and the ion beam such that the ion beam now follows a series of scan lines that extend in a second, different direction relative to the substrate, thereby to implant the substrate in a second pass.

The method further comprises: performing a first part of the first pass according to a first implant depth, changing a property of the ion beam or substrate, and performing a second part of the first pass according to a second implant depth thereby forming first and second regions of the substrate; and performing a first part of the second pass according to a third implant depth, changing a property of the ion beam or substrate, and performing a second part of the second pass according to a fourth implant depth thereby forming third and fourth regions of the substrate. Both the third and fourth regions overlap the first and second regions.

In this way, different regions are formed on the substrate with different doping depth profiles. For example, some regions may have doping only at a narrow range of depths, whereas other regions may have doping over a far greater range of depths. Moreover, when combined with changing other properties of the ion beam and/or substrate, other variations with depth may be achieved. As an example, some depths may be more heavily doped than other depths, or the dopant may be varied between different doping depths.

There may be some commonality between the implant depths, say the third implant depth is the same as the first implant depth.

Optionally, the method according to either aspect may comprise causing a relative rotation of 90°, for example by rotating the substrate through 90°. However, other angles may be chosen. The ion beam may be scanned in the same direction relative to the substrate, but the substrate may be rotated between the first and second relative movements to ensure that they are not parallel. Optionally, causing relative movement comprises mechanically scanning the substrate relative to a substantially fixed ion beam. Preferably, causing relative movement makes the ion beam scan across the substrate according to a raster. Adjacent scan lines may be traced in the same direction or reverse directions.

The present invention also extends to an ion implanter arranged to operate in accordance with any of the methods described above. Operation of the ion implanter may conveniently be controlled by a controller that is arranged to implement any of the methods described above. The controller may take a hardware or software form, e.g. the controller may be provided by a suitably-programmed computer. Hence, the present invention also extends to a computer program comprising program instructions that, when loaded into the controller, cause the controller to control the ion implanter to operate in accordance with any of the methods described above. The present invention also extends to a computer-readable medium having such a computer program recorded thereon.

### BRIEF DESCRIPTION OF THE DRAWINGS

In order that the invention may be more readily understood, exemplary embodiments of the present invention will now be described with reference to the accompanying drawings, in which:

FIG. 1 is a schematic view of an ion implanter having a wafer holder for serial processing of wafers;

FIG. 2 is a schematic representation showing an ion beam scanning across a wafer;

FIG. 3 shows a wafer divided into three dosing stripes;

FIG. 4 shows a wafer subjected to two passes of three dosing stripes, wherein the wafer has been rotated through 90° between passes thereby providing nine implant areas on the wafer;

FIG. 5 corresponds to FIG. 4, but shows a wafer subjected to different dosing recipes; and

FIG. 6 shows a wafer divided into three dosing stripes, wherein the dosing is gradually varied during each dosing stripe.

### DESCRIPTION OF THE PREFERRED EMBODIMENTS

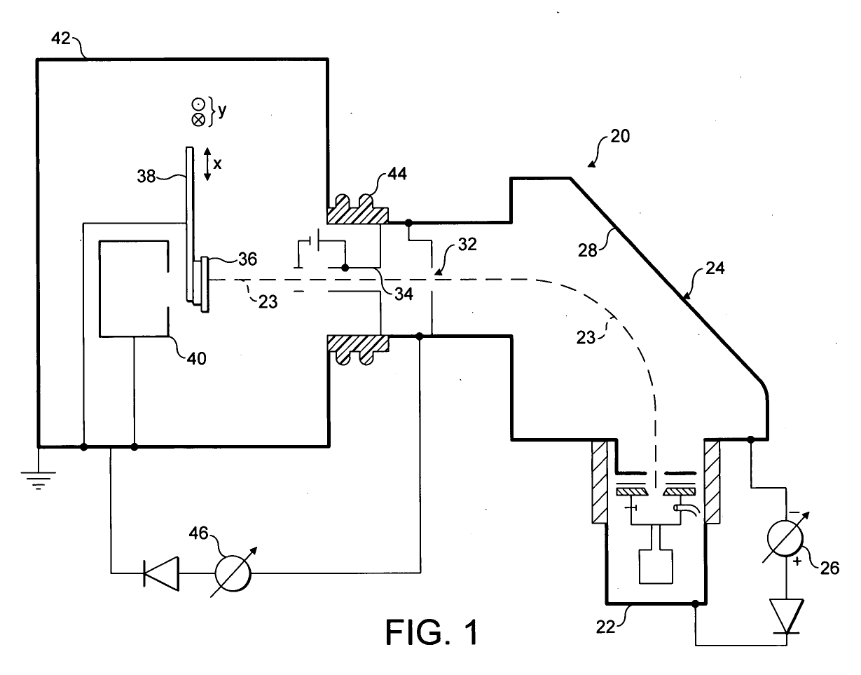

FIG. 1 shows a typical ion implanter 20 comprising an ion beam source 22 such as a Freeman or Bernas ion source that is supplied with a pre-cursor gas for producing an ion beam 23 to be implanted into a wafer 36. The ions generated in the ion source 22 are extracted by an extraction electrode assembly. The flight tube 24 is electrically isolated from the ion source 22 and a high-tension power supply 26 supplies a potential difference therebetween.

This potential difference causes positively charged ions to be extracted from the ion source 22 into the flight. tube 24. The flight tube 24 includes a mass-analysis arrangement comprising a mass-analysing magnet 28 and a mass-resolving slit 32. Upon entering the mass-analysis apparatus within the flight tube 24, the electrically charged ions are deflected by the magnetic field of the mass-analysis magnet 28. The radius and curvature of each ion's flight path is defined, through a constant magnetic field, by the mass/charge ratio of the individual ions.

The mass-resolving slit 32 ensures that only ions having a chosen mass/charge ratio emerge from the mass analysis arrangement. The ion beam 23 is then turned by the mass-analysing magnet 28 to travel along the plane of the paper. Ions passing through the mass-resolving slit 32 enter a tube 34 that is electrically connected to and integral with the flight tube 24. The mass-selected ions exit the tube 34 as an ion beam 23 and strike a semiconductor wafer 36 mounted upon a wafer holder 38. A beamstop 40 is located behind (i.e. downstream of) the wafer holder 38 to intercept the ion beam 23 when not incident upon the wafer 36 or wafer holder 38. The wafer holder 38 is a serial processing wafer holder 38 and so only holds a single wafer 36. The wafer holder 38 is operable to move along X and Y axes, the direction of the ion beam 23 defining the Z axis of a Cartesian coordinate system. As can be seen from FIG. 1, the X axis extends parallel to the plane of the paper, whereas the Y axis extends into and out from the plane of the paper.

To maintain the ion beam current at an acceptable level, an ion extraction energy is set by a regulated high-tension power supply 26: the flight tube 24 is at a negative potential relative to the ion source 22 by virtue of this power supply 26. The ions are maintained at this energy throughout the flight tube 24 until they emerge from the tube 34. It is often desirable for the energy with which the ions impact the wafer 36 to be considerably lower than the extraction energy. In this case, a reverse bias voltage must be applied between the wafer 36 and the flight tube 24. The wafer holder 38 and beamstop 40 are contained within a process chamber 42 that is mounted relative to the flight tube 24 by insulating standoffs 44. Both the beamstop 40 and wafer holder 38 are connected to the flight tube 24 via a deceleration power supply 46. The beamstop 40 and wafer holder 38 are held at a common ground potential so that, to decelerate the positively-charged ions, the deceleration power supply 46 generates a negative potential with respect to the grounded wafer holder 38 and beamstop 40 at the flight tube 24.

In some situations, it is desirable to accelerate the ions prior to implantation in the wafer 36. This is most easily achieved by reversing the polarity of the power supply 46. In other situations, the ions are left to drift from flight tube 24 to wafer 36, i.e. without acceleration or deceleration. This can be achieved by providing a switched current path to short out the power supply 46.

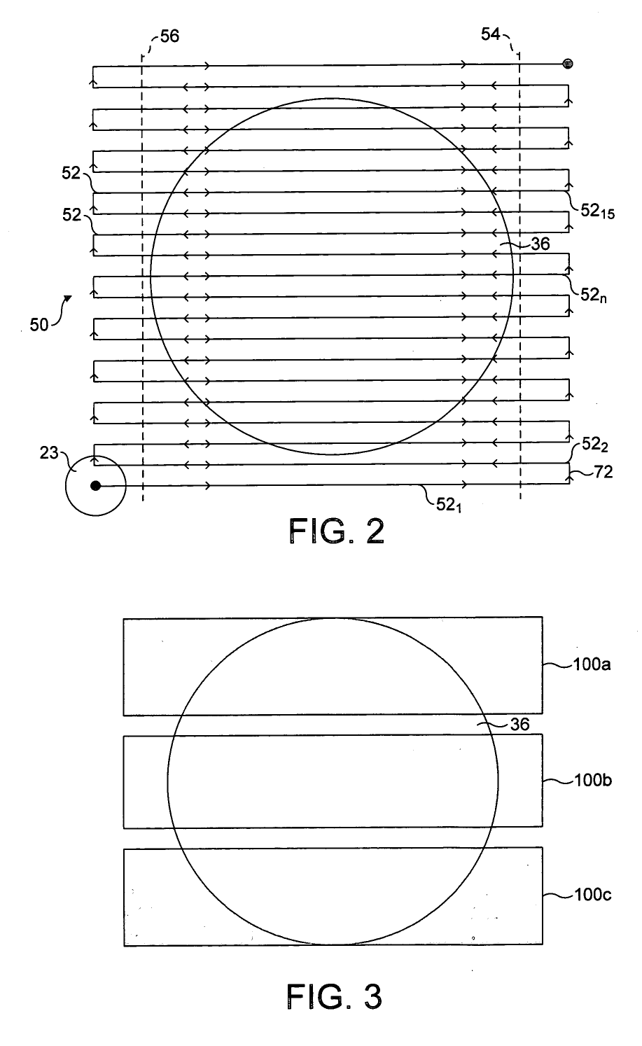

Movement of the wafer holder 38 is controlled such that the fixed ion beam 23 scans across the wafer 36 according to the raster pattern 50 shown in FIG. 2. Although the wafer 36 is scanned relative to a fixed ion beam 23, the raster pattern 50 of FIG. 2 is equivalent to the ion beam 23 being scanned over a stationary wafer 36 (and this method is in fact used in some ion implanters). As imagining a scanning ion beam 23 is more intuitive, the following description will follow this convention although in fact the ion beam 23 is stationary and it is the wafer 36 that is scanned.

The ion beam 23 is scanned over the wafer 36 to form a raster pattern 50 of parallel, spaced scan lines 52₁ to 52ₙ, where n is the number of scan lines. Each movement along a scan line 52ₙ will be referred to herein as a ‘scan’, whilst each complete raster scan 50 will be referred to herein as a ‘pass’. Each wafer implant process is likely to comprise many individual ‘passes’.

The ion beam 23 has a typical diameter of 50 mm, whereas the wafer 36 has a diameter of 300 mm (200 mm also being common for semiconductor wafers). In this example, a pitch of 2 mm in the Y-axis direction is chosen, leading to a total of 175 scan lines (i.e. n=175) to ensure the full extent of the ion beam 23 is scanned over the full extent of the wafer 36. Only 21 scan lines are shown in FIG. 2 for the sake of clarity.

The raster pattern 50 for each pass is formed by scanning the ion beam 23 forwards along the X-axis direction to form the first scan line 52₁ until the ion beam is completely clear of the wafer 36, by moving the ion beam 23 up along the Y-axis direction as shown at 72, by scanning the ion beam 23 backwards along the X-axis direction until completely clear of the wafer 36 once more to form scan line 52₂, by moving the ion beam 23 up along the Y-axis direction, and so on until the whole wafer 36 has seen the ion beam 23 thus completing the pass. As can be seen, each scan line 52ₙ is of a common length, the length being sufficient such that the ion beam 23 is completely clear of the wafer 36 at the start and end of the middle scan line 52_{n/2} that corresponds to the fullest width of the wafer 36. Using scan lines 52ₙ of a common length is not essential; shorter scan lines 52ₙ may be used at the top and bottom of the wafer 36 that still ensure the ion beam 23 is completely clear of the wafer 36 at the start and end of each scan line 52ₙ.

Obviously, other scan patterns are possible. For example, scan lines may be formed in only one direction, i.e. always left to right or always right to left. Also, a single pass may only implant some of the scan lines 52ₙ, i.e. a first pass may implant the odd scan lines 52_{1, 3, 5, . . .} and a second pass may implant the even scan lines 52_{2, 4, 6, . . .} . Thus, a complete implant may comprises a series of interlaced passes. Although straight scan lines are preferred, curved paths may be used. This in fact is the case for batch processing where multiple wafers are rotated on a spoked wheel while the ion beam in scanned radially: a raster pattern of a series of arcuate scan lines extending in the same direction (i.e. right to left or left to right depending upon the rotation of the spoked wheel) is formed across each wafer.

FIG. 3 shows a wafer 36 that has been divided into three dosing stripes 100a, 100b and 100c that correspond to the top, middle and bottom thirds of the wafer 36 respectively. Each dosing stripe 100 corresponds to an area of the wafer 36 to be implanted according to a unique recipe. Put another way, the dosing recipe is changed between dosing stripes 100 such that a property of the ion beam 23 or wafer 36 is changed to affect the dosing that the next dosing stripe 100 receives.

Each dosing stripe 100 occupies substantially one-third of the wafer 36. FIG. 3 shows the dosing stripes 100 to be separated vertically. This separation is exaggerated for the sake of clarity. In fact, only a small gap is left between each dosing stripe 100 to allow for inaccuracies in the implant process. Alternatively, each dosing stripe 100 may abut its neighbour(s) such that there is no gaps between the dosing stripes 100.

As will be evident from the foregoing description, each of the three dosing stripes 100 that occupies substantially one third of the wafer 36 comprises a plurality of scan lines 52ₙ. Put another way, to complete dosing of each scanning stripe 100, the ion beam 23 is scanned across the wafer 36 along many scan lines 52ₙ to dose the entire dosing stripe 100.

Once the bottom dosing stripe 100c is implanted, a property of the implant is adjusted with the ion beam 23 clear of the wafer 36. If this is a property of the ion beam 23, the ion beam 23 is allowed to settle before implanting the next dosing stripe 100b is started. Once dosing the middle dosing stripe 100b has been completed, the process is repeated such that a property of the implant is changed before the top dosing stripe 100a is implanted.

Once this pass that sees the entire wafer 36 implanted is complete, the wafer is rotated and the process may be repeated such that dosing stripes are implanted once more. However, the scan lines 52ₙ comprising each dosing stripe in the second pass will be in a different, non-parallel direction.

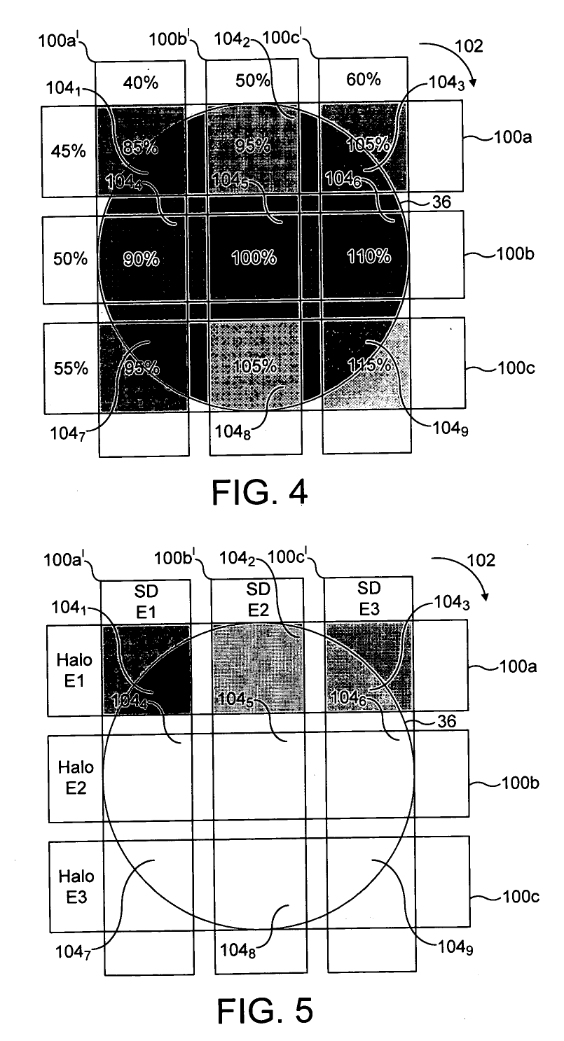

FIG. 4 provides a specific example of such an implant. Similarly to FIG. 3, FIG. 4 uses three dosing stripes 100a, 100b, 100c that divide the wafer 36 into thirds. The first, bottom dosing stripe 100c is implanted using a first ion beam current to provide a relative dose of 55%. Once the ion beam 23 is clear of the wafer 36, the ion beam current is decreased to a second value to provide a relative dose of 50%. The ion beam 23 is allowed to settle and checked using a Faraday detector or the like that may be provided by the beamstop 40. Once the ion beam 23 has settled, the middle dosing stripe 100b is implanted. Once the ion beam 23 is clear of the wafer 36, the ion beam current is again decreased to provide a relative dose of 45% and the ion beam 23 allowed to settle once more. Then, the top dosing stripe 100a is implanted.

The wafer 36 is then rotated through 90° clockwise, as indicated at 102, to allow further dosing to be performed by scanning the ion beam 23 in the X direction. The rotation of the wafer 36 means that the dosing stripes 100′ of the second pass, and hence the scan lines 52ₙ, extend orthogonally to the dosing stripes 100 of the first pass.

The implantation process is repeated for the second pass, i.e. using three dosing stripes 100′ that divide the wafer 35 into thirds. This time the ion beam currents are kept the same, but the scanning speeds are changed between each dosing stripe 100′ to provide different relative doses. The bottom dosing stripe 100c′ is exposed to a relative dose of 60%, the middle dosing stripe 100b′ is exposed to a relative dose of 50% and the top dosing stripe 100c′ is exposed to a relative dose of 40%.

The pattern formed by the two orthogonal passes, each pass comprising three dosing stripes, divides the wafer 36 into nine implant areas 104₁₋₉. Each implant area corresponds to the overlap between two dosing stripes 100 and 100′. The varying relative doses across the dosing stripes 100 and 100′ produces implant areas that have a different total relative doses as follows:
implant area 104₁ receives 85%;
implant area 104₄ receives 90%;
implant areas 104₂ and 104₇ receive 95%;
implant area 104₅ receives 100%;
implant areas 104₃ and 104₈ receive 105%;
implant area 104₆ receives 110%; and
implant area 104₉ receives 115%.

Thus, the wafer 36 provides a map of differently dosed devices, with decreasing doses along each axis. One axis will correspond to decreasing ion beam current and the other axis will correspond to increasing scan speeds.

As mentioned above, the gap between each dosing stripe 100 and 100′ has been exaggerated in FIGS. 3 and 4. Hence, the gaps between the implant areas 104 are also exaggerated.

FIG. 5 corresponds to FIG. 4 in that it shows a wafer 36 dosed in two passes, each pass comprising three horizontal dosing stripes 100, 100′, and with a 90° rotation of the wafer 36 between passes. Again this creates a wafer 36 having nine different implant areas 104.

The first pass is performed using halo implants for each dosing stripe 100 (indicated by “halo” in FIG. 5). The ion beam energy is varied between each dosing stripe 100, thereby altering the depth of implant. The three energies are indicated by E1, E2 and E3 for dosing stripes 100a, 100b and 100c respectively. After rotation of the wafer 36, the second pass is performed using source drain implants for the three dosing stripes 100′ (indicated by “SD”). Again, the three different energies are used for each dosing stripe (E1, E2 and E3 for 100a′, 100b′ and 100c′ respectively). Accordingly, a wafer 36 is obtained that has nine different implant areas. The nine different areas 104 can be identified as:
104₁ is Halo_E1/SD_E1;
104₂ is Halo_E1/SD_E2;
104₃ is Halo_E1/SD_E3;
104₄ is Halo_E2/SD_E1;
104₅ is Halo_E2/SD_E2;
104₅ is Halo_E2/SD_E3;
104₇ is Halo_E3/SD_E1;
104₈ is Halo_E3/SD_E2; and
104₉ is Halo_E3/SD_E3.

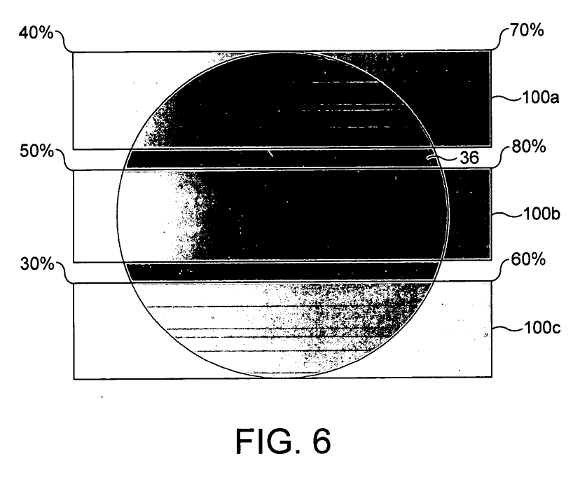

A further variation on the above-described embodiments is that, in addition to changing a property of the implant between dosing stripes 100 and 100′, a property may be changed during all or some of the dosing stripes 100 and 100′. Such an embodiment is shown in FIG. 6 where the wafer is once more divided into three dosing stripes 100. For each dosing stripe 100, the ion beam current is steadily increased from left to right. The top dosing stripe 100a is exposed to a relative ion beam current that varies from 40% to 70%; the middle dosing stripe 100b is exposed to a relative ion beam current that varies from 50% to 80%; and the bottom dosing stripe 100c is exposed to a relative ion beam current that varies from 30% to 60%. In this way a map may be formed on a wafer 36 that shows gradual variation of recipe properties across the wafer 36 rather than the incremental variation previously described.

This implant may be achieved using the raster scan 50 of alternating scan line directions shown in FIG. 2. The ion beam current is gradually increased and next gradually decreased for successive scan lines 52ₙ. Alternatively, all scan lines 52ₙ may be performed in the same direction in which case the ion beam current is always increased or only decreased across each scan line 52ₙ.

This implant arrangement results in the right-hand side of the wafer 36 receiving a higher dose than the left. Other properties may be changed such that, for example, the implant depth varies across each dosing stripe 100. This method may be repeated for multiple passes (with a rotation of the wafer 36 between passes) or some passes may be performed using uniform dosing across each dosing stripe 100, 100′, etc.

It will be evident to the person skilled in the art that variations may be made to the above embodiments without departing from the scope of the invention defined by the accompanying claims.

For example, only three different properties have been described in the above embodiments, namely ion beam current, ion beam energy and implant type (halo and source/drain). Other properties of the implant may also be varied between dosing stripes 100 and 100′. Examples include the position of the substrate (e.g. the substrate may be tilted relative to the ion beam such that the angle of incidence varies), the scanning speed of the ion beam/substrate holder, the overlap between adjacent scan lines, the ion beam species, the ion beam profile, the ion beam divergence or the operational settings of the plasma flood system. Only one property may be varied between dosing stripes 100 and 100′ or between passes, or more than one property may be varied.

All of the above embodiments have been described using an example of three dosing stripes 100 and 100′. However, any number of dosing stripes 100 and 100′ may be chosen. In addition to having multiple dosing stripes 100 and 100′, only a single dosing stripe 100 and 100′ that does not cover the entire wafer 36 may be used. For example, the entire wafer 36 may be subjected to a uniform implant (say the whole wafer 36 is implanted using two dosing stripes 100 with relative ion beam currents of 25% and 50%): the wafer 36 is then rotated through 90° before being implanted with a single dosing stripe 100′ with a relative beam current of 50%. This will create four implant regions 104 with total relative ion beam currents of 25%, 50%, 75% and 100%.

The term “stripe” is appropriate for the embodiments described above where the wafer 36 is notionally divided into horizontal bands. However, the wafer 36 may be divided into any arbitrary shapes and these shapes need not correspond to stripes.

As will be understood, the present invention requires dosing to be performed in two non-parallel directions using different dosing recipes. The above embodiments use 90° rotations between implants, but this need not be the case. Any angle may be chosen, other than 180°, 360°, etc. that would result in a parallel direction. The rotation is relative between the wafer 36 and the ion beam 23. While the above embodiments describe a rotation of the wafer 36 while keeping the ion beam scanning directions fixed, the reverse arrangement could be used. Specifically, the wafer 36 may be kept fixed, but the ion beam 23 may be controlled to scan across the wafer 36 in the Y direction before shifting in the X direction to scan once more in the Y direction. This would effectively see the raster pattern 50 shown in FIG. 2 rotate through 90°.

Moreover, the relative motion between ion beam 23 and wafer 36 may be varied between (i) keeping the wafer 36 fixed and scanning the ion beam 23, (ii) keeping the ion beam 23 fixed and moving the wafer 36, and (iii) a hybrid of scanning both wafer 36 and ion beam 23.

The number of passes may also be varied from the two described above. Any number of passes may be chosen to suit needs. In addition, the raster pattern 50 may be varied as has already been described.

Whilst the embodiments have been described in the context of serial processing of a single wafer 36, the present invention may also be applied to batch processing of wafers 36. When applied to the spoked wheel arrangement described previously, a series of arcuate scan lines 52ₙ results for each pass. After each pass, the wafers 36 may be rotated around their own axis at the end of each spoke and the spoked wheel then rotated once more to form another pass of arcuate scan lines 52ₙ that cross those of the first pass at the angle through which the wafer 36 was rotated. Moreover, each pass may be divided into dosing stripes 100 and 100′ by stopping rotation of the wheel part-way through a pass, changing a property of the implant, and then starting rotation of the wheel and continuing the pass.

The present invention has application generally across the many different fields of implant in addition to the semiconductor wafer processing described above.

1. A method of implanting a substrate using an ion beam, comprising:
causing relative movement between the substrate and the ion beam such that the ion beam scans across the substrate along a series of scan lines that extend in a first direction relative to the substrate, thereby to implant the substrate in a first pass;
causing relative rotation between the substrate and the ion beam; and
repeating the step of causing relative movement between the substrate and the ion beam such that the ion beam now follows a series of scan lines that extend in a second, different direction relative to the substrate, thereby to implant the substrate in a second pass;
further comprising:
performing a first part of the first pass according to a first implant recipe, changing a first property of the ion beam or substrate, and performing a second part of the first pass according to a second implant recipe thereby forming first and second regions of the substrate; and
performing a first part of the second pass according to a third implant recipe, changing a second, different property of the ion beam or substrate, and performing a second part of the second pass according to a fourth implant recipe thereby forming third and fourth regions of the substrate; wherein
both the third and fourth regions overlap the first and second regions.

2. The method of claim 1, wherein the first and third implant recipes are the same.

3. The method of claim 1, wherein changing the first property or the second property of the ion beam or the substrate comprises any one of changing the ion beam current, the ion beam energy, the ion beam profile, the ion beam divergence, the angle of incidence of the ion beam on the substrate, the speed of the relative motion between the ion beam and substrate, the overlap between scan lines traced by the ion beam over the substrate, the ion beam species, the operational settings of the plasma flood system, or any combination thereof.

4. A method of implanting a substrate using an ion beam, comprising:
causing relative movement between the substrate and the ion beam such that the ion beam scans across the substrate along a series of scan lines that extend in a first direction relative to the substrate, thereby to implant the substrate in a first pass;
causing relative rotation between the substrate and the ion beam; and
repeating the step of causing relative movement between the substrate and the ion beam such that the ion beam now follows a series of scan lines that extend in a second, different direction relative to the substrate, thereby to implant the substrate in a second pass;
further comprising:
performing a first part of the first pass according to a first implant depth, changing a property of the ion beam or substrate, and performing a second part of the first pass according to a second implant depth thereby forming first and second regions of the substrate; and
performing a first part of the second pass according to a third implant depth, changing a property of the ion beam or substrate, and performing a second part of the second pass according to a fourth implant depth thereby forming third and fourth regions of the substrate;
wherein
both the third and fourth regions overlap the first and second regions.

5. The method of claim 4, wherein the third implant depth is the same as the first implant depth.

6. The method of claim 1 or claim 4, comprising causing a relative rotation of 90°.

7. The method of claim 6, wherein causing the relative rotation comprises rotating the substrate through 90°.

8. The method of claim 1 or claim 4, wherein causing relative movement comprises mechanically scanning the substrate relative to a substantially fixed ion beam.

9. The method of claim 1 or claim 4, wherein causing relative movement makes the ion beam scan across the substrate according to a raster.

10. An ion implanter arranged to operate in accordance with the method of claim 1 or claim 4.

11. An ion implanter comprising a controller arranged to control the ion implanter to operate in accordance with the method of claim 1 or claim 4.

12. A computer program comprising program instructions that, when loaded into the controller of claim 11, cause the controller to control the ion implanter to operate in accordance with the method of claim 1 or claim 4.

13. A computer-readable medium having the computer program of claim 12 recorded thereon.
